(19) United States
(12) Patent Application Publication
(10) Pub. No.: US 2026/0276749 A1
(43) Pub. Date: Sep. 17, 2026

(54) MAGNETIC SENSOR AND MAGNETIC RECORDING DEVICE

(71) Applicants: Kabushiki Kaisha Toshiba, Kawasaki-shi (JP); Toshiba Electronic Devices & Storage Corporation, Kawasaki-shi (JP)

(72) Inventors: Junki Numata, Kawasaki Kanagawa (JP); Yuji Nakagawa, Kawasaki Kanagawa (JP); Masayuki Takagishi, Kunitachi Tokyo (JP); Naoyuki Narita, Funabashi Chiba (JP); Tomoyuki Maeda, Kawasaki Kanagawa (JP)

(21) Appl. No.: 19/532,558

(22) Filed: Feb. 6, 2026

(30) Foreign Application Priority Data
Mar. 11, 2025 (JP) 2025-038346

(51) Int. Cl. G01R 33/09

(52) U.S. Cl. CPC G01R 33/093

(57) ABSTRACT

According to one embodiment, a magnetic sensor includes a first conductive portion, a second conductive portion, a sensor portion, and a controller. The sensor portion is provided between the first conductive portion and the second conductive portion. The sensor portion includes a first magnetic member, a first non-magnetic member, and a first insulating member. The first insulating member is between the first magnetic member and the first non-magnetic member in a second direction crossing a first direction from the first conductive portion to the second conductive portion. The first non-magnetic member includes a first portion and a second portion. The second portion is between the first portion and the second conductive portion in the first direction. The controller is configured to supply first current between the first conductive portion and the second conductive portion and to detect a first signal generated between the first portion and the second portion.

### CROSS-REFERENCE TO RELATED APPLICATIONS

This application is based upon and claims the benefit of priority from Japanese Patent Application No. 2025-038346, filed on Mar. 11, 2025; the entire contents of which are incorporated herein by reference.

### FIELD

Embodiments described herein relate generally to a magnetic sensor and a magnetic recording device.

### BACKGROUND

A magnetic head including a magnetic sensor is used to reproduce information recorded on a magnetic recording medium such as a hard disk drive (HDD). Improved characteristics of the magnetic sensor are desired.

### BRIEF DESCRIPTION OF THE DRAWINGS

FIG. 1 is a schematic diagram illustrating a magnetic sensor according to a first embodiment;

FIGS. 2A to 2C are schematic diagrams illustrating the operation of the magnetic sensor according to the first embodiment;

FIG. 3 is a schematic diagram illustrating a magnetic sensor according to the first embodiment;

FIGS. 4A and 4B are schematic diagrams illustrating magnetic sensors according to the first embodiment;

FIGS. 5A and 5B are schematic diagrams illustrating magnetic sensors according to the first embodiment;

FIGS. 6A and 6B are schematic diagrams illustrating magnetic sensors according to the first embodiment;

FIG. 7 is a schematic diagram illustrating a magnetic sensor according to the first embodiment;

FIG. 8 is a schematic diagram illustrating a magnetic sensor according to the first embodiment;

FIG. 9 is a schematic diagram illustrating a magnetic sensor according to the first embodiment;

FIG. 10 is a schematic diagram illustrating a magnetic sensor according to the first embodiment;

FIG. 11 is a schematic diagram illustrating a magnetic sensor according to the first embodiment;

FIG. 12 is a schematic diagram illustrating a magnetic sensor according to the first embodiment;

FIGS. 13A and 13B are schematic diagrams illustrating a magnetic sensor according to the first embodiment;

FIG. 14 is a schematic diagram illustrating a magnetic sensor according to a second embodiment;

FIG. 15 is a schematic diagram illustrating a magnetic sensor according to a third embodiment;

FIG. 16 is a schematic cross-sectional view illustrating an application of the magnetic sensor according to the embodiment;

FIG. 17 is a schematic perspective view illustrating a magnetic recording device according to an embodiment;

FIG. 18 is a schematic perspective view illustrating a magnetic recording device according to an embodiment;

FIG. 19 is a schematic perspective view illustrating a part of a magnetic recording device according to an embodiment;

FIG. 20 is a schematic perspective view illustrating the magnetic recording device according to the embodiment; and

FIGS. 21A and 21B are schematic perspective views illustrating a part of the magnetic recording device according to the embodiment.

### DETAILED DESCRIPTION

According to one embodiment, a magnetic sensor includes a first conductive portion, a second conductive portion, a sensor portion, and a controller. The sensor portion is provided between the first conductive portion and the second conductive portion. The sensor portion includes a first magnetic member, a first non-magnetic member, and a first insulating member. The first insulating member is between the first magnetic member and the first non-magnetic member in a second direction crossing a first direction from the first conductive portion to the second conductive portion. The first non-magnetic member includes a first portion and a second portion. The second portion is between the first portion and the second conductive portion in the first direction. The controller is configured to supply a first current between the first conductive portion and the second conductive portion and to detect a first signal generated between the first portion and the second portion.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

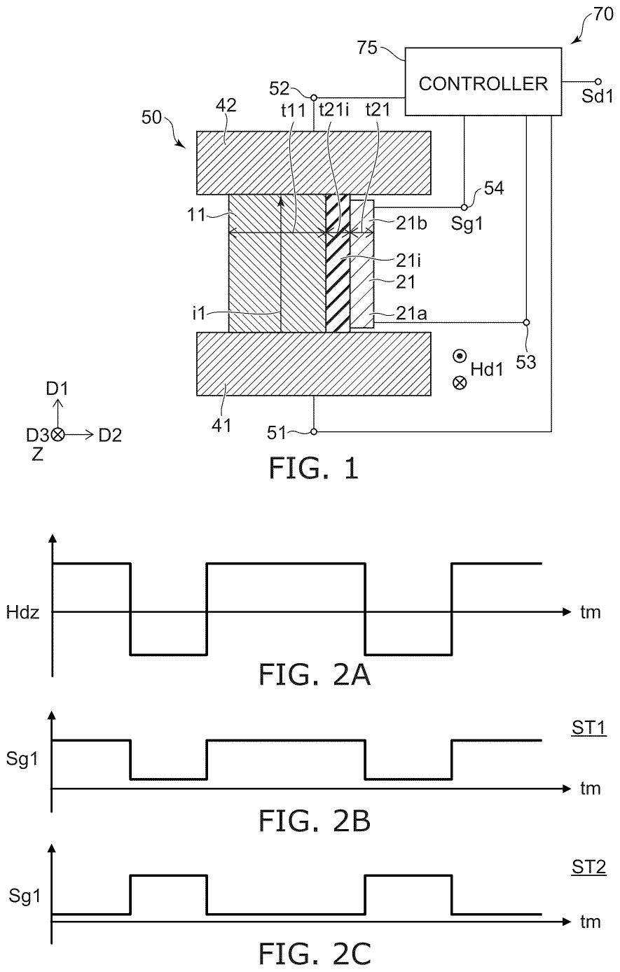

FIG. 1 is a schematic diagram illustrating a magnetic sensor according to a first embodiment.

As shown in FIG. 1, a magnetic sensor 70 according to the embodiment includes a first conductive portion 41, a second conductive portion 42, a sensor portion 50, and a controller 75.

The sensor portion 50 is provided between the first conductive portion 41 and the second conductive portion 42. The sensor portion 50 includes a first magnetic member 11, a first non-magnetic member 21, and a first insulating member 21i. The first insulating member 21i is between the first magnetic member 11 and the first non-magnetic member 21 in a second direction D2. The second direction D2 crosses a first direction D1 from the first conductive portion 41 to the second conductive portion 42.

The first non-magnetic member 21 includes a first portion 21a and a second portion 21b. The second portion 21b is between the first portion 21a and the second conductive portion 42 in the first direction D1. In this example, the first portion 21a is separated from the first conductive portion 41. The second portion 21b is separated from the second conductive portion 42. As described later, the first portion 21a may contact the first conductive portion 41, and the second portion 21b may contact the second conductive portion 42.

The controller 75 is electrically connected to the first conductive portion 41 and the second conductive portion 42. In this example, the sensor portion 50 includes a first terminal 51 and a second terminal 52. The first terminal 51 is electrically connected to the first conductive portion 41. The second terminal 52 is electrically connected to the second conductive portion 42. In this example, the sensor portion 50 includes a third terminal 53 and a fourth terminal 54. The third terminal 53 is electrically connected to the first portion 21a. The fourth terminal 54 is electrically connected to the second portion 21b.

The controller 75 is configured to supply a first current i1 between the first conductive portion 41 and the second conductive portion 42 and detect a first signal Sg1 generated between the first portion 21a and the second portion 21b.

The first signal Sg1 changes in response to a target magnetic field Hd1. For example, the first signal Sg1 changes in response to the component of the target magnetic field Hd1 in a third direction D3. The third direction D3 crosses a plane including the first direction D1 and the second direction D2.

The third direction D3 is, for example, a Z-axis direction. The first direction D1 may be a direction along a plane perpendicular to the X-Y plane perpendicular to the Z-axis direction. The second direction D2 may be another direction along a plane perpendicular to the X-Y plane perpendicular to the Z-axis direction.

As described above, in the embodiment, the first signal Sg1 changes in response to a component of the target magnetic field Hd1 in the third direction D3. The first signal Sg1 changes in conjunction with the change in the target magnetic field Hd1.

FIGS. 2A to 2C are schematic diagrams illustrating the operation of the magnetic sensor according to the first embodiment.

The horizontal axis in these diagrams is time tm. The vertical axis in FIG. 2A is a component Hdz along the third direction D3 of the target magnetic field Hd1. The vertical axis in FIG. 2B is the first signal Sg1 in a first state ST1. The vertical axis in FIG. 2C is the first signal Sg1 in a second state ST2.

As shown in FIG. 2A, the component Hdz along the third direction D3 of the target magnetic field Hd1 changes. For example, the polarity of the component Hdz changes in response to a change in the orientation of the target magnetic field Hd1.

As shown in FIG. 2B, in the first state ST1, the first signal Sg1 changes in conjunction with the change in the component Hdz. In the first state ST1, the polarity of the fluctuating component of the first signal Sg1 is the same as the polarity of the target magnetic field Hd1.

As shown in FIG. 2C, in the second state ST2, the first signal Sg1 changes in conjunction with changes in the component Hdz. In the second state ST2, the polarity of the fluctuating component of the first signal Sg1 is opposite to the polarity of the target magnetic field Hd1.

The above-mentioned change in the first signal Sg1 is considered to be due to, for example, an action of the component Hdz of the target magnetic field Hd1 in the third direction D3 and the first current i1 in the sensor portion 50 including the first magnetic member 11 and the first non-magnetic member 21. For example, the first signal Sg1 is considered to reflect the “magnetic spin Hall effect.”

In the embodiment, the target magnetic field Hd1 is detected based on the first signal Sg1. The target magnetic field Hd1 can be detected with high sensitivity and high accuracy. According to the embodiment, a magnetic sensor capable of improving characteristics can be provided.

The controller 75 may be configured to output a detection signal Sd1 obtained by processing the first signal Sg1. The processing may include various types of processing such as amplification, noise removal, and AD conversion.

The polarity of the fluctuation of the first signal Sg1 may be determined, for example, by the orientation of the first current i1 and the characteristics of the material included in the sensor portion 50.

In the embodiment, the first magnetic member 11 includes at least one selected from the group consisting of Co₂MnGa, Co₂MnAl, Co₃Sn₂S₂, FePt, MnGa, Mn₃Sn, Mn₃Ge, Mn₃Ga, RuO₂, MnTe, CrSb, FeSb₂, KRu₄O₈, and Mn₅Si₃.

The first non-magnetic member 21 includes at least one selected from the group consisting of Pt, W, Ta, Bi, Cu, Au, Ag, Al, Pd, Ru, Ir, Hf, Nb, Mo, and Ph.

In the embodiment, spin information of the first magnetic member 11 may be transmitted to the first non-magnetic member 21.

A thickness of the first insulating member 21i along the second direction D2 is defined as a first insulating member thickness t21i. A thickness of the first magnetic member 11 along the second direction D2 is defined as a first magnetic member thickness t11. A thickness of the first non-magnetic member 21 along the second direction D2 is defined as a first non-magnetic member thickness t21. For example, the first insulating member thickness t21i may be thinner than the first magnetic member thickness t11. For example, the first signal Sg1 that changes with high sensitivity is easily obtained.

For example, the first non-magnetic member thickness t21 may be thinner than the first magnetic member thickness t11. For example, the first signal Sg1 that changes with high sensitivity is easily obtained. For example, the first insulating member thickness t21i may be not more than the first non-magnetic member thickness t21.

The first insulating member thickness t21i may be, for example, not less than 0.5 nm and not more than 5.0 nm. The first magnetic member thickness t11 may be, for example, not less than 1.0 nm and not more than 25.0 nm. The first non-magnetic member thickness t21 may be, for example, not less than 0.5 nm and not more than 5.0 nm.

In the embodiment, the first conductive portion 41 and the second conductive portion 42 may function, for example, as a shield. The first conductive portion 41 and the second conductive portion 42 may include, for example, at least one selected from the group consisting of Ni and Fe.

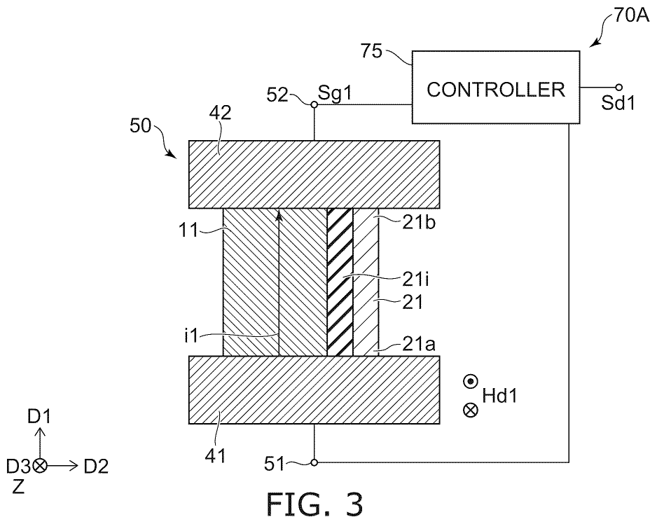

FIG. 3 is a schematic diagram illustrating a magnetic sensor according to the first embodiment.

As shown in FIG. 3, in a magnetic sensor 70A according to the embodiment, the configuration of the sensor portion 50 is different from that of the sensor portion 50 in the magnetic sensor 70. The configuration of the magnetic sensor 70A except for this may be the same as the configuration of the magnetic sensor 70.

In the magnetic sensor 70A, the first portion 21a contacts the first conductive portion 41. The second portion 21b contacts the second conductive portion 42.

The sensor portion 50 includes the first terminal 51 electrically connected to the first conductive portion 41 and the second terminal 52 electrically connected to the second conductive portion 42. The controller 75 may be configured to supply the first current i1 between the first terminal 51 and the second terminal 52, and to detect the first signal Sg1 generated between the first terminal 51 and the second terminal 52.

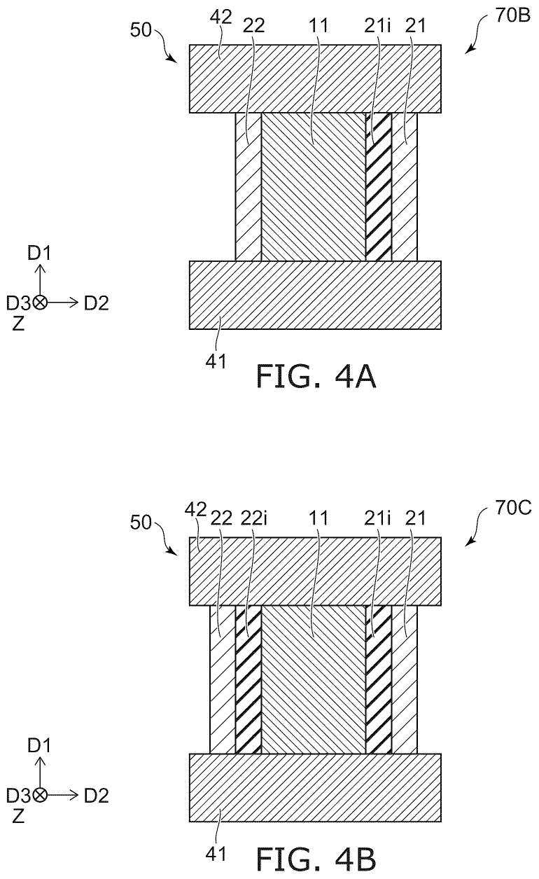

FIGS. 4A and 4B are schematic diagrams illustrating magnetic sensors according to the first embodiment.

As shown in FIG. 4A, in a magnetic sensor 70B according to the embodiment, the sensor portion 50 further includes a second non-magnetic member 22. The configuration of the magnetic sensor 70B except for this may be the same as the configuration of the magnetic sensor 70 or the magnetic sensor 70A.

In the magnetic sensor 70B, the first magnetic member 11 is between the second non-magnetic member 22 and the first insulating member 21i in the second direction D2. The first magnetic member 11 contacts the second non-magnetic member 22. In the magnetic sensor 70B, by providing two non-magnetic members, higher sensitivity and higher accuracy can be obtained. The characteristics can be further improved.

As shown in FIG. 4B, in a magnetic sensor 70C according to the embodiment, the sensor portion 50 further includes a second non-magnetic member 22 and a second insulating member 22i. The configuration of the magnetic sensor 70C except for this may be the same as the configuration of the magnetic sensor 70 or the magnetic sensor 70A.

In the magnetic sensor 70C, the first magnetic member 11 is between the second non-magnetic member 22 and the first insulating member 21i in the second direction D2. The second insulating member 22i is between the second non-magnetic member 22 and the first magnetic member 11 in the second direction D2. Higher accuracy can be obtained with higher sensitivity. The characteristics can be further improved.

The material of the second non-magnetic member 22 may be the same as the material of the first non-magnetic member 21. The material of the second insulating member 22i may be the same as the material of the first insulating member 21i.

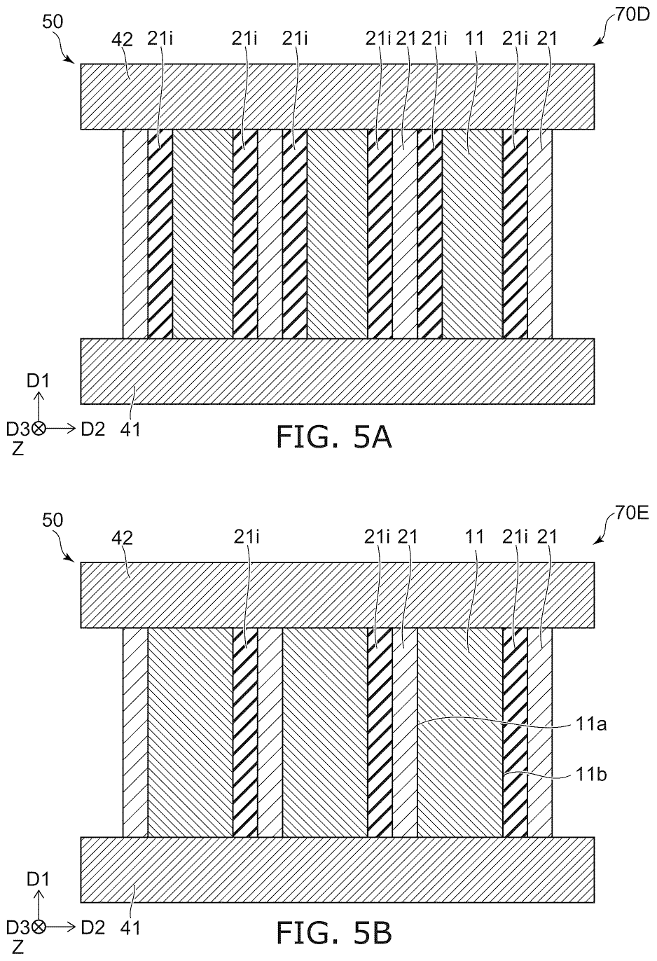

FIGS. 5A and 5B are schematic diagrams illustrating magnetic sensors according to the first embodiment.

As shown in FIGS. 5A and 5B, in a magnetic sensor 70D and a magnetic sensor 70E according to the embodiment, the sensor portion 50 includes a plurality of first magnetic members 11 and a plurality of first non-magnetic members 21. The configuration of magnetic sensor 70D and the magnetic sensor 70E except for this may be the same as the configuration of magnetic sensor 70 or magnetic sensor 70A.

In the magnetic sensor 70D and the magnetic sensor 70E, the plurality of first magnetic members 11 are between one of the plurality of first non-magnetic members 21 and another one of the plurality of first non-magnetic members 21. The first insulating member 21i may be provided at least in a first position or a second position. The first position is between one of the plurality of first magnetic members 11 and one of the plurality of first non-magnetic members 21. The second position is between one of the plurality of first magnetic members 11 and another one of the plurality of first non-magnetic members 21.

As shown in FIG. 5B, in a magnetic sensor 70E, one of the plurality of first magnetic members 11 includes a first face 11a and a second face 11b. The first face 11a faces one of the plurality of first non-magnetic members 21. The second face 11b faces another one of the plurality of first non-magnetic members 21. The second face 11b is between the first face 11a and the other of the plurality of first non-magnetic members 21 in the second direction D2. The first face 11a contacts the one of the plurality of first non-magnetic members 21. The first insulating member 21i is provided between the second face 11b and the other one of the plurality of first non-magnetic members 21.

In magnetic sensor 70E, the configuration of the sensor portion 50 is asymmetric in the second direction D2. For example, a temperature gradient is formed. This results in, for example, the Nernst effect. Higher sensitivity is obtained.

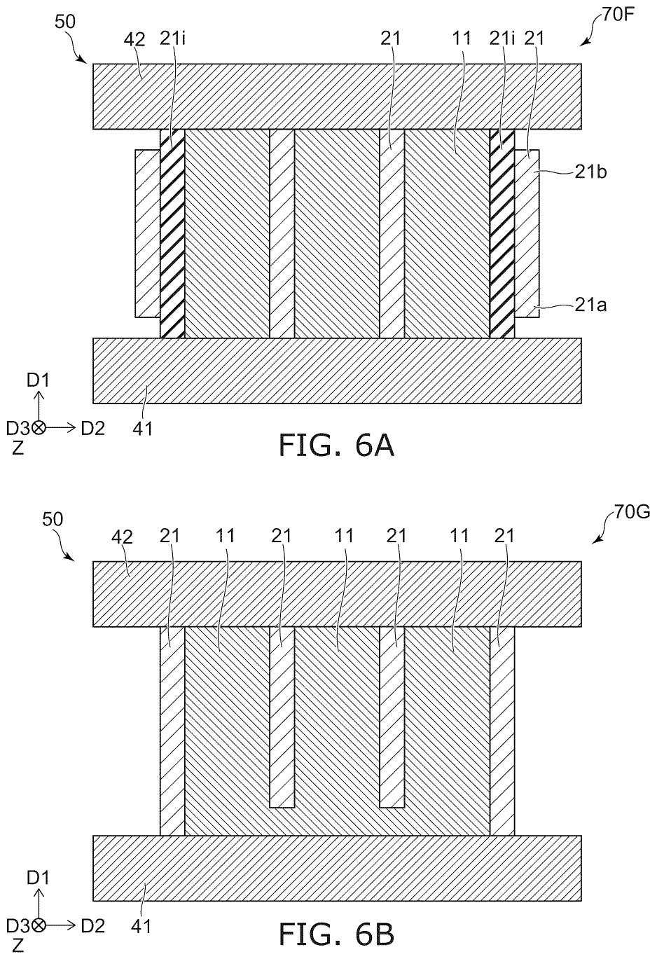

FIGS. 6A and 6B are schematic diagrams illustrating magnetic sensors according to the first embodiment.

As shown in FIG. 6A, in a magnetic sensor 70F according to the embodiment, the configuration of sensor portion 50 differs from the configuration of sensor portion 50 in magnetic sensor 70D or magnetic sensor 70E. The configuration of the magnetic sensor 70F except for this may be the same as the configuration of magnetic sensor 70, etc.

In the magnetic sensor 70F, the sensor portion 50 includes the plurality of first magnetic members 11 and the plurality of first non-magnetic members 21. Two of the first non-magnetic members 21 provided at the ends in the second direction D2 are separated from the first conductive portion 41 and the second conductive portion 42. The first non-magnetic members 21 except for these two are in contact with the first conductive portion 41 and the second conductive portion 42.

As shown in FIG. 6B, in a magnetic sensor 70G according to the embodiment, some of the first magnetic members 11 are continuous with each other. The configuration of the magnetic sensor 70G except for this may be the same as the configuration of the magnetic sensor 70. In this example, one end of each of the first magnetic members 11 is continuous with each other.

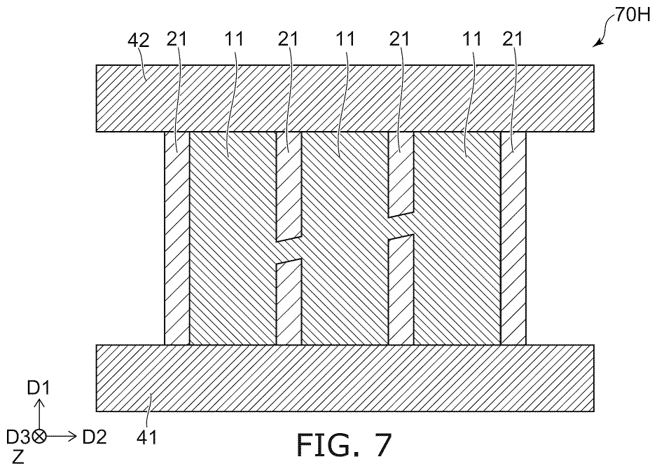

FIG. 7 is a schematic diagram illustrating a magnetic sensor according to the first embodiment.

As shown in FIG. 7, in a magnetic sensor 70H according to the embodiment, some of the plurality of first magnetic members 11 are continuous with each other. The configuration of the magnetic sensor 70H except for this may be the same as the configuration of the magnetic sensor 70, etc. In this example, one of the plurality of first magnetic members 11 and another one of the plurality of first magnetic members 11 are continuous with each other in their intermediate portions in the first direction D1.

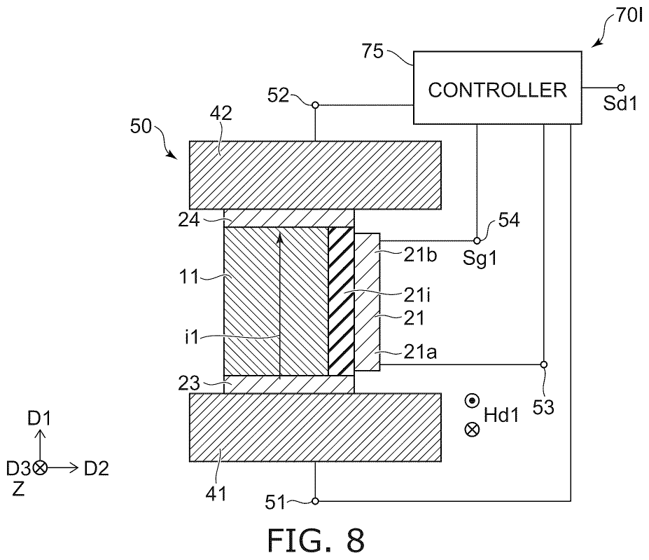

FIG. 8 is a schematic diagram illustrating a magnetic sensor according to the first embodiment.

As shown in FIG. 8, in a magnetic sensor 70I according to the embodiment, the sensor portion 50 further includes a third non-magnetic member 23. The configuration of the magnetic sensor 70I except for this may be the same as the configuration of the magnetic sensor 70 or the magnetic sensor 70A.

The third non-magnetic member 23 is between the first conductive portion 41 and the first magnetic member 11. In this example, the sensor portion 50 further includes a fourth non-magnetic member 24. The fourth non-magnetic member 24 is between the first magnetic member 11 and the second conductive portion 42. By providing the third non-magnetic member 23, for example, the interaction between the first magnetic member 11 and the first conductive portion 41 is reduced. By providing the fourth non-magnetic member 24, for example, the interaction between the first magnetic member 11 and the second conductive portion 42 is reduced. Higher sensitivity is obtained.

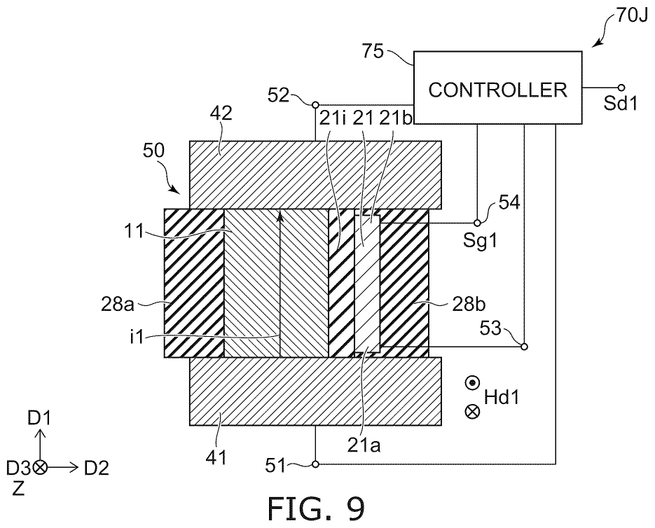

FIG. 9 is a schematic diagram illustrating a magnetic sensor according to the first embodiment.

As shown in FIG. 9, in a magnetic sensor 70J according to the embodiment, the sensor portion 50 includes a first structure 28a and a second structure 28b. The configuration of the magnetic sensor 70J except for this may be the same as the configuration of the magnetic sensor 70 or the magnetic sensor 70A.

A position of the first magnetic member 11 in the second direction D2 (first magnetic member position) is between a position of the first structure 28a in the second direction D2 (first structure position) and a position of the second structure 28b in the second direction D2 (second structure position). The first thermal conductivity of the first structure 28a is different from the second thermal conductivity of the second structure 28b.

The difference in thermal conductivity causes a temperature difference at two different positions in the second direction D2. For example, heat is generated by a current flowing through the first magnetic member 11. The difference in heat propagation causes a temperature difference. A heat flow having a component along the second direction D2 is generated. The sensor portion 50 has a temperature gradient along the second direction D2. In the magnetic sensor 70J, for example, the Nernst effect is obtained. Higher sensitivity is obtained.

The first structure 28a and the second structure 28b may be, for example, a non-magnetic insulating member. The first structure 28a and the second structure 28b may be in contact with the first magnetic member 11. The first structure 28a and the second structure 28b may be, for example, a non-magnetic conductive member. The first structure 28a may include, for example, at least one selected from the group consisting of Cu, SiC, Al, W, Mo, Au, Ag, AlN, BN, Al₂O₃, and Y₂O₅. The second structure 28b may include, for example, at least one selected from the group consisting of Ta, GaAs, Ti, SiO₂, Si₃N₄, TiO₂, MgO, HfO₂, ZrO₂, and Nb₂O₅.

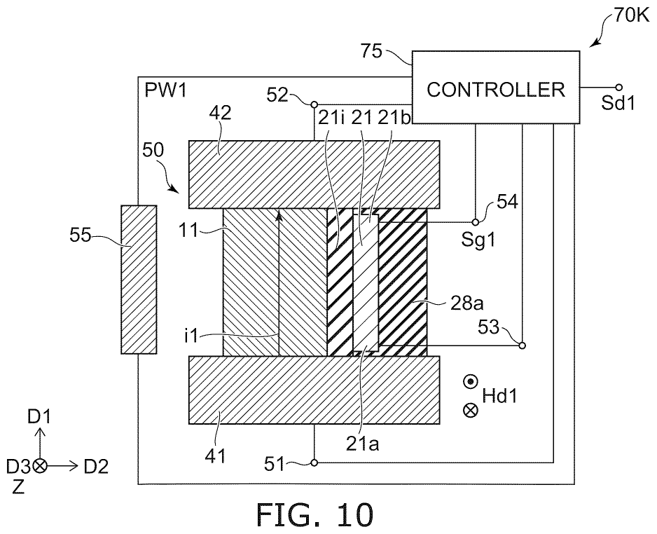

FIG. 10 is a schematic diagram illustrating a magnetic sensor according to the first embodiment.

As shown in FIG. 10, a magnetic sensor 70K according to the embodiment further includes a temperature control element 55. The configuration of the magnetic sensor 70K except for this may be the same as the configuration of the magnetic sensor 70.

In the magnetic sensor 70K, the controller 75 is configured to change the temperature of the temperature control element 55. In one example, the temperature control element 55 is a conductive member (e.g., a heater). The controller 75 supplies a first power PW1 to the temperature control element 55. The first power PW1 increases the temperature of the temperature control element 55. For example, a direction from the temperature control element 55 to the sensor portion 50 includes a component in the second direction D2. The increase in temperature causes a temperature distribution in the sensor portion 50. The sensor portion 50 has a temperature gradient having a component in the second direction D2. In the magnetic sensor 70K, for example, the Nernst effect is obtained. Higher sensitivity is obtained.

In another example, the temperature control element 55 is a Peltier element. The controller 75 supplies a current (first power PW1) to the temperature control element 55. Depending on the orientation of the current, the temperature of the temperature control element 55 increases or decreases. For example, the direction from the temperature control element 55 to the sensor portion 50 includes a component in the second direction D2. The increase or decrease in temperature causes a temperature distribution in the sensor portion 50. The sensor portion 50 has a temperature gradient having a component in the second direction D2. In the magnetic sensor 70K, for example, the Nernst effect is obtained. Higher sensitivity is obtained.

In the magnetic sensor 70K, the direction from the temperature control element 55 to the sensor portion 50 is along the second direction D2.

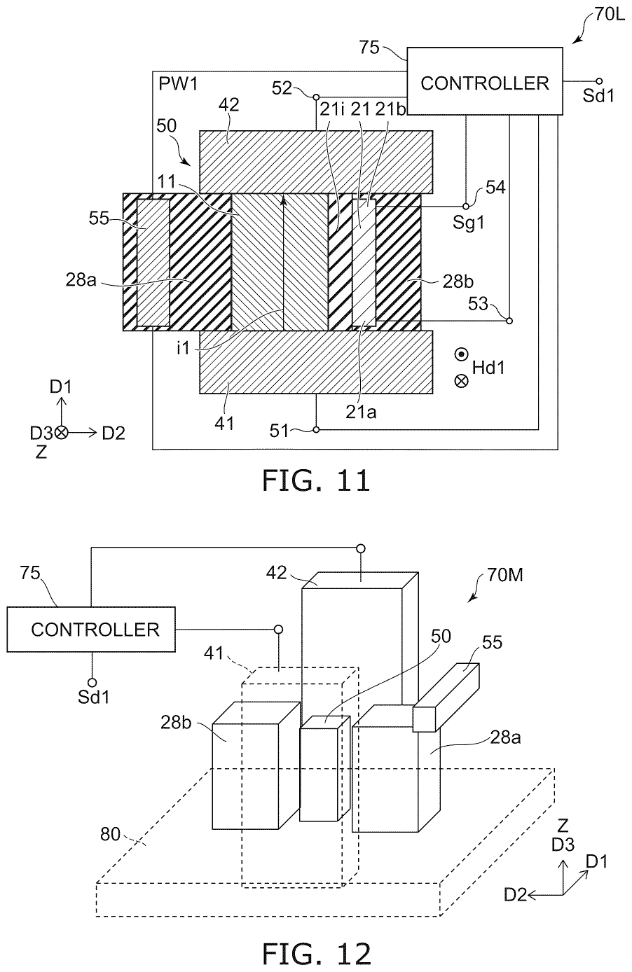

FIG. 11 is a schematic diagram illustrating a magnetic sensor according to the first embodiment.

As shown in FIG. 11, in a magnetic sensor 70L according to the embodiment, the sensor portion 50 includes the temperature control element 55, the first structure 28a, and the second structure 28b. The configuration of the magnetic sensor 70L except for this may be the same as the configuration of the magnetic sensor 70 or the magnetic sensor 70A.

The change in temperature caused by the temperature control element 55 and the anisotropy of the heat dissipation caused by the first structure 28a and the second structure 28b are utilized.

FIG. 12 is a schematic diagram illustrating a magnetic sensor according to the first embodiment.

As shown in FIG. 12, a magnetic sensor 70M according to the embodiment further includes the temperature control element 55. The configuration of the magnetic sensor 70M except for this may be the same as the configuration of the magnetic sensor 70, etc.

The direction from the temperature control element 55 to the sensor portion 50 includes a component of the second direction D2. In the magnetic sensor 70M, the direction from the temperature control element 55 to the sensor portion 50 is along the second direction D2 while being inclined with respect to the second direction D2.

For example, the direction from the magnetic recording medium 80 to the sensor portion 50 is along the third direction D3. For example, the position of the temperature control element 55 in the third direction D3 may be different from the position of the sensor portion 50 in the third direction D3. The position of the sensor portion 50 in the third direction D3 may be between the position of the magnetic recording medium 80 in the third direction D3 and the position of the temperature control element 55 in the third direction D3.

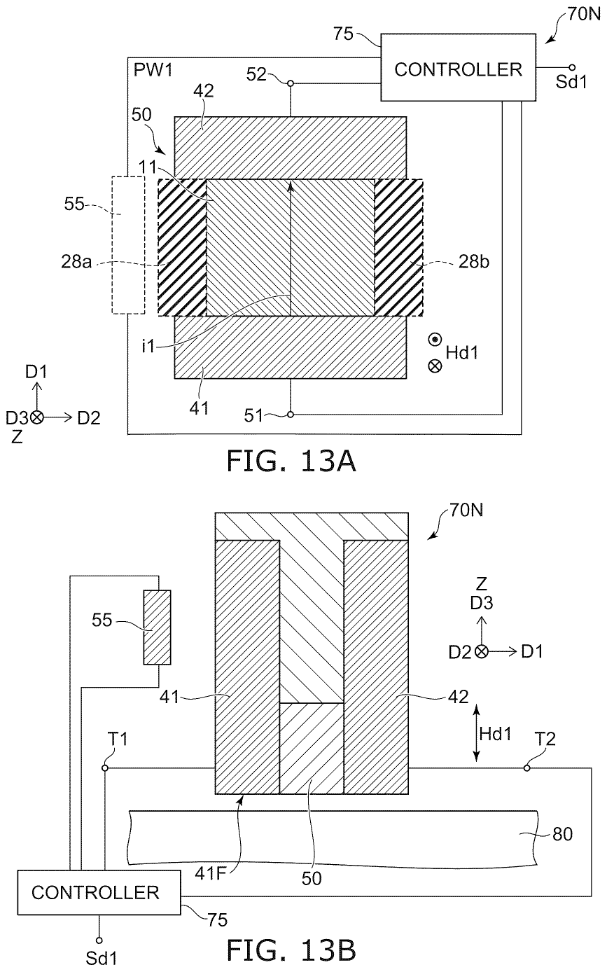

FIGS. 13A and 13B are schematic diagrams illustrating a magnetic sensor according to the first embodiment.

FIG. 13A is a plan view. FIG. 13B is a cross-sectional view. As shown in FIGS. 13A and 13B, a magnetic sensor 70N according to the embodiment includes the temperature control element 55. The configuration of the magnetic sensor 70N except for this may be the same as the configuration of the magnetic sensor 70, etc.

The direction from the temperature control element 55 to the sensor portion 50 includes a component that crosses the third direction D3. For example, the direction from the temperature control element 55 to the sensor portion 50 may include a component of the second direction D2. In the magnetic sensor 70N, the direction from the temperature control element 55 to the sensor portion 50 may be along the second direction D2 while being inclined with respect to the second direction D2.

As shown in FIG. 13B, the magnetic sensor 70N may include an end face 41F in the third direction D3. In a case where the magnetic sensor 70N is applied to a magnetic head, the end face 41F corresponds to the medium-facing face. For example, the position of the first conductive portion 41 in the third direction D3 may be between the position of the end face 41F in the third direction D3 and the position of the temperature control element 55 in the third direction D3.

In a case where the magnetic sensor 70N is applied to a magnetic head, a heater for adjusting the flying height of the magnetic head may be applied as the temperature control element 55. In the embodiment, the temperature control element 55 may be provided separately from the heater for adjusting the flying height of the magnetic head. At least one of the first structure 28a or the second structure 28b may be provided in the magnetic sensor 70N. The first thermal conductivity of the first structure 28a is different from the second thermal conductivity of the second structure 28b.

As shown in FIG. 13B, the direction from the temperature control element 55 to the sensor portion 50 may include a component of the first direction D1.

### Second Embodiment

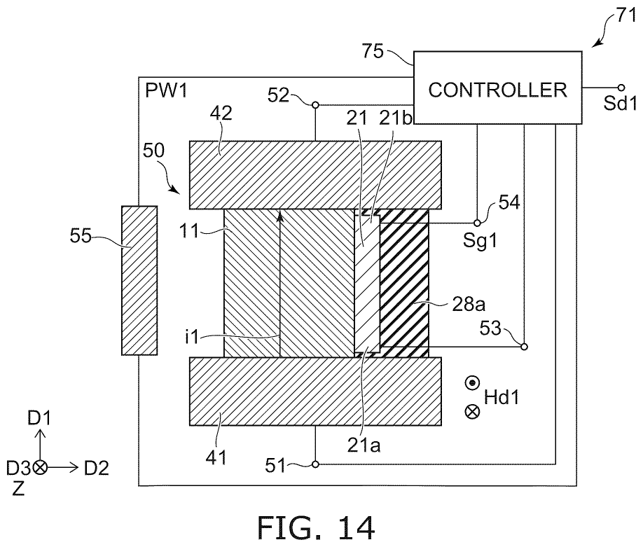

FIG. 14 is a schematic diagram illustrating a magnetic sensor according to a second embodiment.

As shown in FIG. 14, a magnetic sensor 71 according to the embodiment includes the first conductive portion 41, the second conductive portion 42, the sensor portion 50, the temperature control element 55, and the controller 75.

The sensor portion 50 is provided between the first conductive portion 41 and the second conductive portion 42. The sensor portion 50 includes the first magnetic member 11 and the first non-magnetic member 21. The second direction D2 from the first magnetic member 11 to the first non-magnetic member 21 crosses the first direction D1 from the first conductive portion 41 to the second conductive portion 42. The first non-magnetic member 21 includes the first portion 21a and the second portion 21b. The second portion 21b is between the first portion 21a and the second conductive portion 42 in the first direction D1.

The controller 75 is configured to supply the first current i1 between the first conductive portion 41 and the second conductive portion 42 and to supply the first power PW1 to the temperature control element 55. The controller 75 is configured to detect the first signal Sg1 generated between the first portion 21a and the second portion 21b.

In the magnetic sensor 71, the first signal Sg1 that changes with higher sensitivity can be obtained.

For example, the direction from the temperature control element 55 to the sensor portion 50 includes a component in the second direction D2. The temperature control element 55 may be, for example, a conductive member (heater). The temperature control element 55 may be, for example, a Peltier element. The temperature of the temperature control element 55 increases or decreases due to the first power PW1. The sensor portion 50 has a temperature gradient along the second direction D2.

As shown in FIG. 14, the sensor portion 50 may further include the first structure 28a. In this example, the first magnetic member 11 and the first non-magnetic member 21 are provided between the temperature control element 55 and the first structure 28a. The first structure 28a functions as, for example, a heat sink. A stable temperature gradient is obtained.

The magnetic sensor 71 may include the first structure 28a and the second structure 28b having different thermal conductivities. The position of the first magnetic member 11 in the second direction D2 (first magnetic member position) is between the position of the first structure 28a in the second direction D2 (first structure position) and the position of the second structure 28b in the second direction D2 (second structure position).

In the magnetic sensor 71, the first non-magnetic member 21 may be in contact with the first magnetic member 11. The configuration described in relation to the first embodiment may be applied to the magnetic sensor 71.

### Third Embodiment

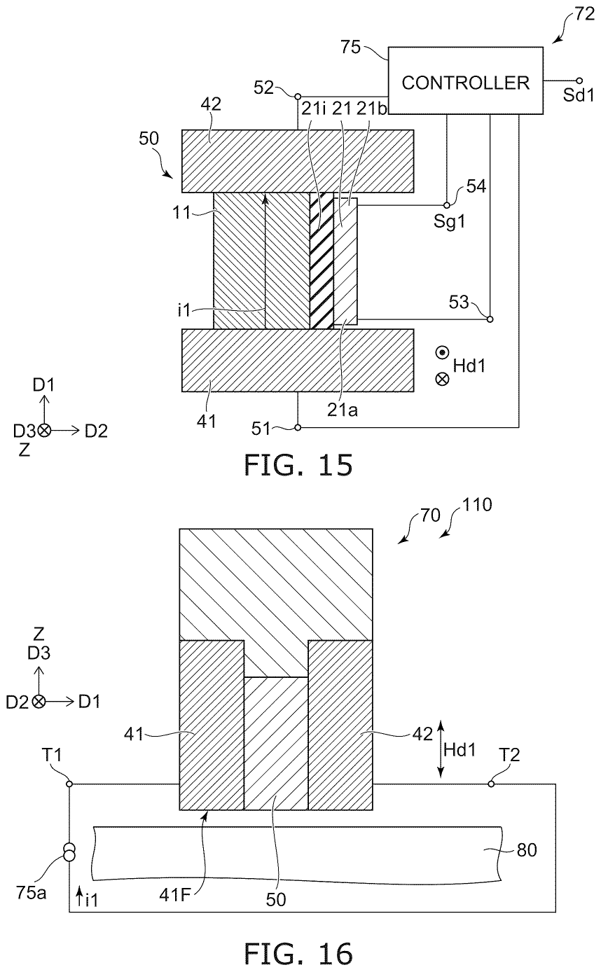

FIG. 15 is a schematic diagram illustrating a magnetic sensor according to a third embodiment.

As shown in FIG. 15, a magnetic sensor 72 according to the embodiment includes the first conductive portion 41, the second conductive portion 42, the sensor portion 50, the first terminal 51, the second terminal 52, the third terminal 53, the fourth terminal 54, and the controller 75.

The sensor portion 50 is provided between the first conductive portion 41 and the second conductive portion 42. The sensor portion 50 includes the first magnetic member 11 and the first non-magnetic member 21. The second direction D2 from the first magnetic member 11 to the first non-magnetic member 21 crosses the first direction D1 from the first conductive portion 41 to the second conductive portion 42. The first non-magnetic member 21 includes the first portion 21a and the second portion 21b. The second portion 21b is located between the first portion 21a and the second conductive portion 42 in the first direction D1.

In this example, the sensor portion 50 includes the first insulating member 21i. The first insulating member 21i is between the first magnetic member 11 and the first non-magnetic member 21 in the second direction D2.

The first terminal 51 is electrically connected to the first conductive portion 41. The second terminal 52 is electrically connected to the second conductive portion 42. The third terminal 53 is electrically connected to the first portion 21a. The fourth terminal 54 is electrically connected to the second portion 21b.

The controller 75 is configured to supply the first current i1 between the first terminal 51 and the second terminal 52, and to detect the first signal Sg1 generated between the third terminal 53 and the fourth terminal 54. The first signal Sg1 changes in response to the component of the target magnetic field Hd1 in the third direction D3. The third direction D3 crosses a plane including the first direction D1 and the second direction D2.

In the magnetic sensor 72 as well, the first signal Sg1, which changes with high sensitivity can be obtained. This provides a magnetic sensor with improved characteristics.

FIG. 16 is a schematic cross-sectional view illustrating an application of the magnetic sensor according to the embodiment.

As shown in FIG. 16, the magnetic sensor 70 (or any of the magnetic sensors described above) may be applied to a magnetic head 110. The direction from the magnetic recording medium 80 to the magnetic head 110 may be along the third direction D3. For example, the controller 75 may include a current source 75a provided between the first conductive portion 41 and the second conductive portion 42. The magnetic field from the magnetic recording medium 80 corresponds to the target magnetic field Hd1. The magnetic recording medium 80 moves relative to the magnetic head 110 in a plane crossing the third direction D3.

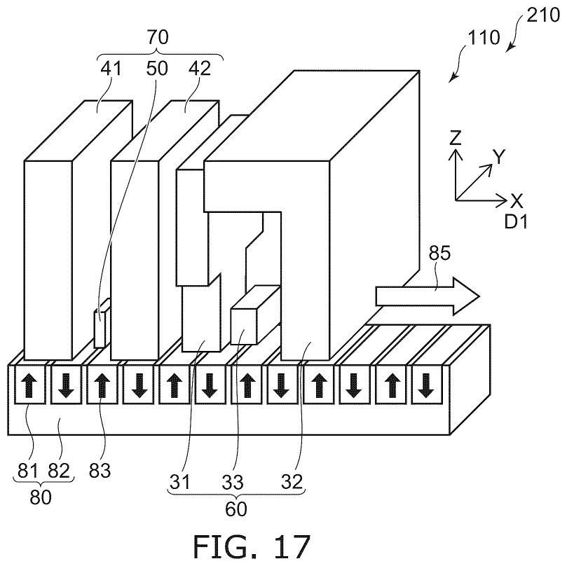

FIG. 17 is a schematic perspective view illustrating a magnetic recording device according to an embodiment.

As shown in FIG. 17, a magnetic recording device 210 according to the embodiment includes a magnetic head 110 including the magnetic sensor 70 according to the embodiment (or another magnetic sensor described above), and the magnetic recording medium 80. The target magnetic field Hd1 corresponds to information recorded on the magnetic recording medium 80. The magnetic sensor 70 corresponds to a reproducing section. The magnetic head 110 may include a recording section 60. Information is recorded on the magnetic recording medium 80 by the recording section 60. The information recorded on the magnetic recording medium 80 is reproduced by the magnetic sensor 70.

The magnetic recording medium 80 includes, for example, a medium substrate 82 and a magnetic recording layer 81 provided on the medium substrate 82. The magnetization 83 of the magnetic recording layer 81 is controlled by the recording section 60. The recording section 60 includes, for example, a first magnetic pole 31 and a second magnetic pole 32. The first magnetic pole 31 is, for example, a main magnetic pole. The second magnetic pole 32 is, for example, a trailing shield. The recording section 60 may include a recording section element 33. The recording section element 33 may include a magnetic field control element or a high-frequency oscillation element. The recording section element 33 may be omitted.

As shown in FIG. 17, the magnetic recording medium 80 moves relative to the magnetic head 110 in the medium movement direction 85. The magnetic head 110 controls information corresponding to the magnetization 83 of the magnetic recording layer 81 at any position. The magnetic head 110 reproduces information corresponding to the magnetization 83 of the magnetic recording layer 81 at any position.

In this example, the first direction D1 from the first conductive portion 41 to the second conductive portion 42 is along an X-axis direction. The X-axis direction is along the down-track direction.

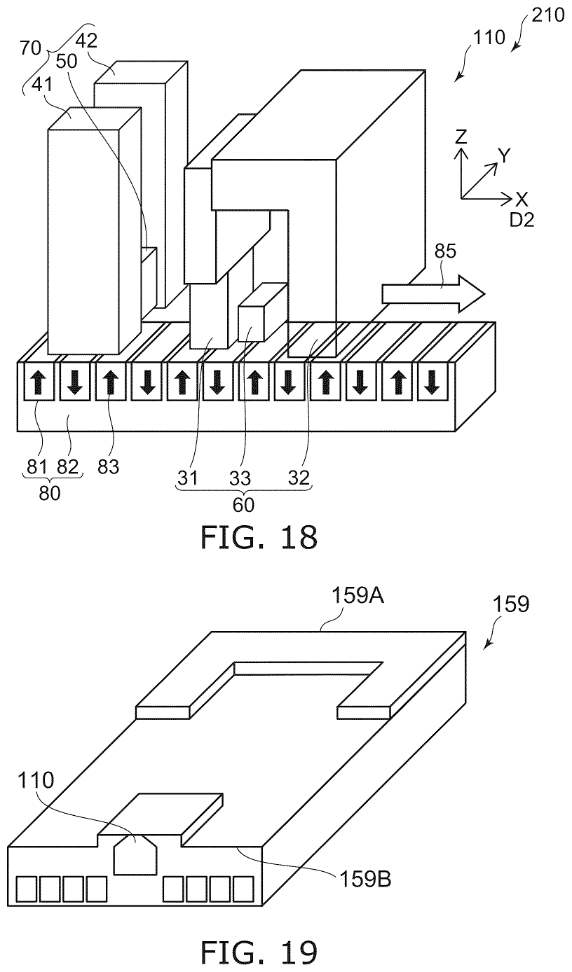

FIG. 18 is a schematic perspective view illustrating a magnetic recording device according to an embodiment.

In the example shown in FIG. 18, the second direction D2 is along the X-axis direction. The X-axis direction is along the down-track direction.

FIG. 19 is a schematic perspective view illustrating a part of a magnetic recording device according to an embodiment.

FIG. 19 illustrates a head slider.

The magnetic head 110 is provided on a head slider 159. The head slider 159 includes, for example, Al₂O₃/TiC. The head slider 159 moves relative to the magnetic recording medium while floating above or in contact with the magnetic recording medium.

The head slider 159 has, for example, an air inflow side 159A and an air outflow side 159B. The magnetic head 110 is disposed on the side of the air outflow side 159B of the head slider 159. As a result, the magnetic head 110 moves relative to the magnetic recording medium while floating above or in contact with the magnetic recording medium.

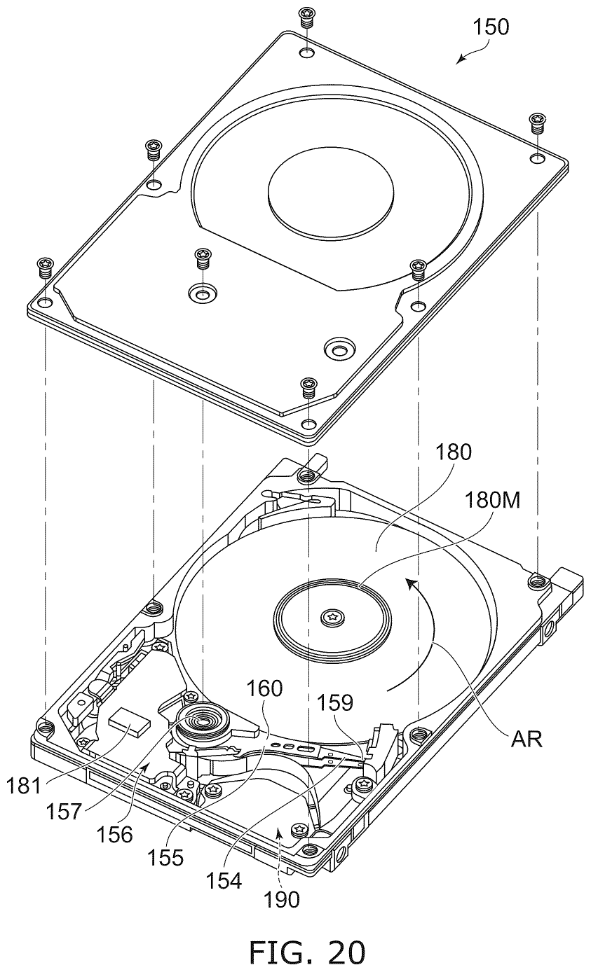

FIG. 20 is a schematic perspective view illustrating the magnetic recording device according to the embodiment.

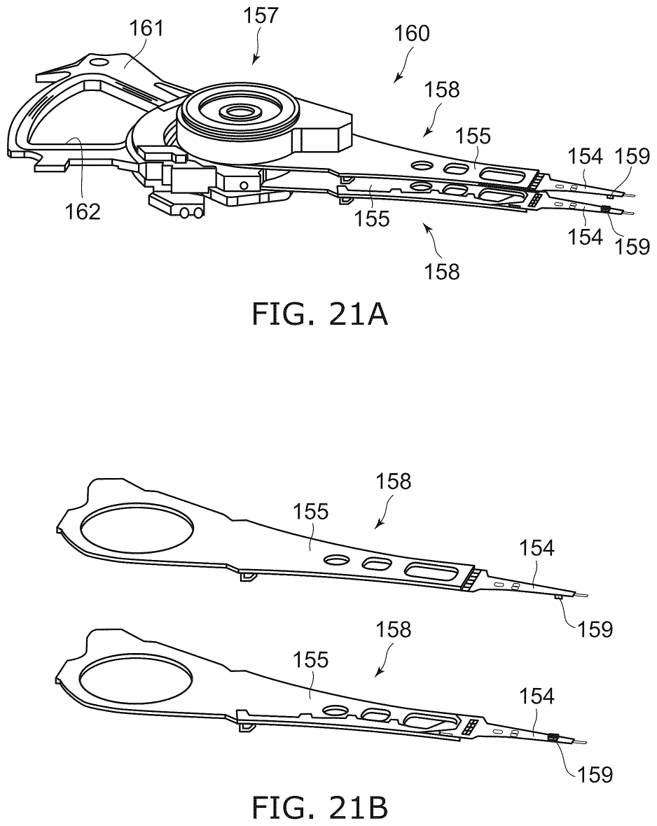

FIGS. 21A and 21B are schematic perspective views illustrating a part of the magnetic recording device according to the embodiment.

As shown in FIG. 20, in a magnetic recording device 150 according to the embodiment, a rotary actuator is used. The recording medium disk 180 is connected to a spindle motor 180M. The recording medium disk 180 is rotated in a direction of arrow AR by the spindle motor 180M. The spindle motor 180M is responsive to control signals from the drive device controller. The magnetic recording device 150 according to the embodiment may include the plurality of recording medium disks 180. The magnetic recording device 150 may include a recording medium 181. The recording medium 181 is, for example, an SSD (Solid State Drive). A non-volatile memory such as a flash memory is used for the recording medium 181, for example. For example, the magnetic recording device 150 may be a hybrid HDD (Hard Disk Drive).

The head slider 159 records and reproduces information to be recorded on the recording medium disk 180. The head slider 159 is provided at an end of a thin-film suspension 154. A magnetic head according to the embodiment is provided near the end of the head slider 159.

While the recording medium disk 180 is rotating, the pressing pressure by the suspension 154 and the floating pressure generated at the medium facing face (ABS) of the head slider 159 are balanced. The distance between the medium facing face of the head slider 159 and the surface of the recording medium disk 180 is the predetermined fly height. In the embodiment, the head slider 159 may contact the recording medium disk 180. For example, a contact sliding type may be applied.

The suspension 154 is connected to one end of an arm 155 (e.g., an actuator arm). The arm 155 includes, for example, a bobbin part or the like. The bobbin part holds a drive coil. A voice coil motor 156 is provided at the other end of the arm 155. The voice coil motor 156 is a type of linear motor. The voice coil motor 156 includes, for example, a drive coil and a magnetic circuit. The drive coil is wound on the bobbin part of the arm 155. The magnetic circuit includes permanent magnets and opposing yokes. The drive coil is provided between the permanent magnet and the opposing yoke. The suspension 154 includes one end and the other end. The magnetic head is provided at one end of the suspension 154. The arm 155 is connected to the other end of the suspension 154.

The arm 155 is held by ball bearings. Ball bearings are provided at two locations above and below a bearing part 157. The arm 155 can be rotated and slid by the voice coil motor 156. The magnetic head can move to any position on the recording medium disk 180.

FIG. 21A is an enlarged perspective view of the head stacked body assembly 160, illustrating the configuration of a part of the magnetic recording device.

FIG. 21B is a perspective view illustrating the magnetic head assembly (head gimbal assembly: HGA) 158 that forms part of the head stacked body assembly 160.

As shown in FIG. 21A, the head stacked body assembly 160 includes the bearing part 157, the magnetic head assembly 158 and a support frame 161. The magnetic head assembly 158 extends from the bearing part 157. The support frame 161 extends from the bearing part 157. A direction in which the support frame 161 extends is opposite to a direction in which the magnetic head assembly 158 extends. The support frame 161 supports a coil 162 of the voice coil motor 156.

As shown in FIG. 21B, the magnetic head assembly 158 includes the arm 155 extending from the bearing part 157 and the suspension 154 extending from the arm 155.

The head slider 159 is provided at the end of the suspension 154. The head slider 159 is provided with the magnetic head according to the embodiment.

The magnetic head assembly 158 (head gimbal assembly) according to the embodiment includes the magnetic head according to the embodiment, the head slider 159 provided with the magnetic head, the suspension 154 and the arm 155. The head slider 159 is provided at one end of the suspension 154. The arm 155 is connected to the other end of the suspension 154.

The suspension 154 may include, for example, a wiring (not shown) for recording and reproducing signals. The suspension 154 may include, for example, a heater wiring (not shown) for adjusting the fly height. The suspension 154 may include a wiring (not shown) for, for example, an oscillator element or the like. These wires may be electrically connected to a plurality of electrodes provided on the magnetic head.

A signal processor 190 is provided in the magnetic recording device 150. The signal processor 190 uses a magnetic head to record and reproduce signals on a magnetic recording medium. Input/output lines of the signal processor 190 are connected to, for example, electrode pads of the magnetic head assembly 158 and electrically connected to the magnetic head.

The magnetic recording device 150 according to the embodiment includes the magnetic recording medium, the magnetic head according to the embodiment, a movable part, a position controller, and a signal processor. The movable part separates the magnetic recording medium from the magnetic head or makes them relatively movable while they are in contact with each other. The position controller aligns the magnetic head with a predetermined recording position on the magnetic recording medium. The signal processor records and reproduces signals on the magnetic recording medium using the magnetic head.

For example, the recording medium disk 180 is used as the above magnetic recording medium. The movable part includes, for example, the head slider 159. The position controller described above includes, for example, the magnetic head assembly 158.

The embodiments may include the following Technical proposals:

### Technical Proposal 1

A magnetic sensor, comprising:
a first conductive portion;
a second conductive portion;
a sensor portion provided between the first conductive portion and the second conductive portion, the sensor portion including a first magnetic member, a first non-magnetic member, and a first insulating member, the first insulating member being between the first magnetic member and the first non-magnetic member in a second direction crossing a first direction from the first conductive portion to the second conductive portion, the first non-magnetic member including a first portion and a second portion, the second portion being between the first portion and the second conductive portion in the first direction; and
a controller,
the controller being configured to supply a first current between the first conductive portion and the second conductive portion and to detect a first signal generated between the first portion and the second portion.

### Technical Proposal 2

The magnetic sensor according to Technical proposal 1, wherein
the first signal changes in response to a target magnetic field.

### Technical Proposal 3

The magnetic sensor according to Technical proposal 1, wherein
the first signal changes in response to a component of the target magnetic field in a third direction, and
the third direction crosses a plane including the first direction and the second direction.

### Technical Proposal 4

The magnetic sensor according to Technical proposal 3, wherein
the first magnetic member includes at least one selected from the group consisting of Co₂MnGa, Co₂MnAl, Co₃Sn₂S₂, FePt, MnGa, Mn₃Sn, Mn₃Ge, Mn₃Ga, RuO₂, MnTe, CrSb, FeSb₂, KRu₄O₈, and Mn₅Si₃, and
the first non-magnetic member includes at least one selected from the group consisting of Pt, W, Ta, Bi, Cu, Au, Ag, Al, Pd, Ru, Ir, Hf, Nb, Mo, and Ph.

### Technical Proposal 5

The magnetic sensor according to Technical proposal 3 or 4, wherein
the sensor portion includes a first terminal electrically connected to the first conductive portion and a second terminal electrically connected to the second conductive portion,
the first portion contacts the first conductive portion,
the second portion contacts the second conductive portion,
the controller supplies the first current between the first terminal and the second terminal, and detects the first signal generated between the first terminal and the second terminal.

### Technical Proposal 6

The magnetic sensor according to any one of Technical proposals 3-5, wherein
the sensor portion further includes a second non-magnetic member,
the first magnetic member is between the second non-magnetic member and the first insulating member in the second direction, and
the first magnetic member is in contact with the second non-magnetic member.

### Technical Proposal 7

The magnetic sensor according to any one of Technical proposals 3-5, wherein
the sensor portion further includes a second non-magnetic member and a second insulating member,
the first magnetic member is between the second non-magnetic member and the first insulating member in the second direction, and
the second insulating member is between the second non-magnetic member and the first magnetic member in the second direction.

### Technical Proposal 8

The magnetic sensor according to any one of Technical proposals 3-5, wherein
the sensor portion includes a plurality of the first magnetic members and a plurality of the first non-magnetic members,
the plurality of the first magnetic members are between one of the plurality of the first non-magnetic members and another one of the plurality of the first non-magnetic members,
the first insulating member is provided at least in a first position and a second position,
the first position is between the one of the plurality of the first magnetic members and the one of the plurality of the first non-magnetic members, and
the second position is between the one of the plurality of the first magnetic members and the other one of the plurality of the first non-magnetic members.

### Technical Proposal 9

The magnetic sensor according to any one of Technical proposals 3-8, further comprising:
a temperature control element,
the controller is configured to change a temperature of the temperature control element.

### Technical proposal 10

The magnetic sensor according to Technical proposal 9, wherein
a direction from the temperature control element to the sensor portion includes a component crossing the third direction.

### Technical Proposal 11

The magnetic sensor according to any one of Technical proposals 3-10, wherein
the sensor portion further includes a first structure and a second structure,
a first magnetic member position in the second direction of the first magnetic member is between a first structure position in the second direction of the first structure and a second structure position in the second direction of the second structure, and
a first thermal conductivity of the first structure is different from a second thermal conductivity of the second structure.

### Technical Proposal 12

A magnetic sensor, comprising:
a first conductive portion;
a second conductive portion;
a sensor portion provided between the first conductive portion and the second conductive portion, the sensor portion including a first magnetic member and a first non-magnetic member, a second direction from the first magnetic member to the first non-magnetic member crossing a first direction from the first conductive portion to the second conductive portion, the first non-magnetic member including a first portion and a second portion, the second portion being between the first portion and the second conductive portion in the first direction;
a temperature control element; and
a controller,
the controller being configured to supply a first current between the first conductive portion and the second conductive portion, to change a temperature of the temperature control element, and to detect a first signal generated between the first portion and the second portion.

### Technical Proposal 13

The magnetic sensor according to Technical proposal 12, wherein
a direction from the temperature control element to the sensor portion includes a component crossing the third direction.

### Technical Proposal 14

The magnetic sensor according to Technical proposal 12 or 13, wherein
the sensor portion further includes a first structure and a second structure,
a first magnetic member position of the first magnetic member in the second direction is between a first structure position of the first structure in the second direction and a second structure position of the second structure in the second direction, and
a first thermal conductivity of the first structure is different from a second thermal conductivity of the second structure.

### Technical Proposal 15

A magnetic sensor, comprising:
a first conductive portion;
a second conductive portion; and
a sensor portion provided between the first conductive portion and the second conductive portion, the sensor portion including a first magnetic member and a first non-magnetic member, a second direction from the first magnetic member to the first non-magnetic member crossing a first direction from the first conductive portion to the second conductive portion, the first non-magnetic member including a first portion and a second portion, the second portion being between the first portion and the second conductive portion in the first direction;
a first terminal electrically connected to the first conductive portion;
a second terminal electrically connected to the second conductive portion;
a third terminal electrically connected to the first portion; and a fourth terminal electrically connected to the second portion; and
a controller,
the controller being configured to supply a first current between the first terminal and the second terminal and to detect a first signal generated between the third terminal and the fourth terminal.

### Technical Proposal 16

The magnetic sensor according to Technical proposal 15, wherein
the first signal changes in response to a component of a target magnetic field in a third direction, and
the third direction crosses a plane including the first direction and the second direction.

### Technical Proposal 17

A magnetic recording device, comprising:
a magnetic head including the magnetic sensor according to any one of Technical proposals 3-11;
a magnetic recording medium,
the target magnetic field corresponds to information recorded on the magnetic recording medium.

### Technical Proposal 18

The magnetic recording device according to Technical proposal 17, wherein
a direction from the magnetic recording medium to the magnetic sensor is along the third direction.

### Technical Proposal 19

The magnetic recording device according to Technical proposal 18, wherein
the first direction is along a down-track direction of the magnetic recording medium.

### Technical Proposal 20

The magnetic recording device according to Technical proposal 18, wherein
the second direction is along a down-track direction of the magnetic recording medium.

According to the embodiment, a magnetic sensor and a magnetic recording device can be provided that can improve the characteristics.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in magnetic sensors and magnetic recording devices such as conductive portions, magnetic members, non-magnetic members, magnetic recording mediums, magnetic heads, controllers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all magnetic heads and all magnetic sensors and all magnetic recording devices practicable by an appropriate design modification by one skilled in the art based on the magnetic sensors and the magnetic recording devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A magnetic sensor, comprising:
a first conductive portion;
a second conductive portion;
a sensor portion provided between the first conductive portion and the second conductive portion, the sensor portion including a first magnetic member, a first non-magnetic member, and a first insulating member, the first insulating member being between the first magnetic member and the first non-magnetic member in a second direction crossing a first direction from the first conductive portion to the second conductive portion, the first non-magnetic member including a first portion and a second portion, the second portion being between the first portion and the second conductive portion in the first direction; and
a controller,
the controller being configured to supply a first current between the first conductive portion and the second conductive portion and to detect a first signal generated between the first portion and the second portion.

2. The magnetic sensor according to claim 1, wherein
the first signal changes in response to a target magnetic field.

3. The magnetic sensor according to claim 1, wherein
the first signal changes in response to a component of the target magnetic field in a third direction, and
the third direction crosses a plane including the first direction and the second direction.

4. The magnetic sensor according to claim 3, wherein
the first magnetic member includes at least one selected from the group consisting of Co₂MnGa, Co₂MnAl, Co₃Sn₂S₂, FePt, MnGa, Mn₃Sn, Mn₃Ge, Mn₃Ga, RuO₂, MnTe, CrSb, FeSb₂, KRu₄O₈, and Mn₅Si₃, and
the first non-magnetic member includes at least one selected from the group consisting of Pt, W, Ta, Bi, Cu, Au, Ag, Al, Pd, Ru, Ir, Hf, Nb, Mo, and Ph.

5. The magnetic sensor according to claim 3, wherein
the sensor portion includes a first terminal electrically connected to the first conductive portion and a second terminal electrically connected to the second conductive portion,
the first portion contacts the first conductive portion,
the second portion contacts the second conductive portion,
the controller supplies the first current between the first terminal and the second terminal, and detects the first signal generated between the first terminal and the second terminal.

6. The magnetic sensor according to claim 3, wherein
the sensor portion further includes a second non-magnetic member,
the first magnetic member is between the second non-magnetic member and the first insulating member in the second direction, and
the first magnetic member is in contact with the second non-magnetic member.

7. The magnetic sensor according to claim 3, wherein
the sensor portion further includes a second non-magnetic member and a second insulating member,
the first magnetic member is between the second non-magnetic member and the first insulating member in the second direction, and
the second insulating member is between the second non-magnetic member and the first magnetic member in the second direction.

8. The magnetic sensor according to claim 3, wherein
the sensor portion includes a plurality of the first magnetic members and a plurality of the first non-magnetic members,
the plurality of the first magnetic members are between one of the plurality of the first non-magnetic members and another one of the plurality of the first non-magnetic members,
the first insulating member is provided at least in a first position and a second position,
the first position is between the one of the plurality of the first magnetic members and the one of the plurality of the first non-magnetic members, and
the second position is between the one of the plurality of the first magnetic members and the other one of the plurality of the first non-magnetic members.

9. The magnetic sensor according to claim 1, further comprising:
a temperature control element,
the controller is configured to change a temperature of the temperature control element.

10. The magnetic sensor according to claim 9, wherein
a direction from the temperature control element to the sensor portion includes a component crossing the third direction.

11. The magnetic sensor according to claim 3, wherein
the sensor portion further includes a first structure and a second structure,
a first magnetic member position in the second direction of the first magnetic member is between a first structure position in the second direction of the first structure and a second structure position in the second direction of the second structure, and
a first thermal conductivity of the first structure is different from a second thermal conductivity of the second structure.

12. A magnetic sensor, comprising:
a first conductive portion;
a second conductive portion;
a sensor portion provided between the first conductive portion and the second conductive portion, the sensor portion including a first magnetic member and a first non-magnetic member, a second direction from the first magnetic member to the first non-magnetic member crossing a first direction from the first conductive portion to the second conductive portion, the first non-magnetic member including a first portion and a second portion, the second portion being between the first portion and the second conductive portion in the first direction;
a temperature control element; and
a controller,
the controller being configured to supply a first current between the first conductive portion and the second conductive portion, to change a temperature of the temperature control element, and to detect a first signal generated between the first portion and the second portion.

13. The magnetic sensor according to claim 12, wherein
a direction from the temperature control element to the sensor portion includes a component crossing the third direction.

14. The magnetic sensor according to claim 12, wherein
the sensor portion further includes a first structure and a second structure,
a first magnetic member position of the first magnetic member in the second direction is between a first structure position of the first structure in the second direction and a second structure position of the second structure in the second direction, and
a first thermal conductivity of the first structure is different from a second thermal conductivity of the second structure.

15. A magnetic sensor, comprising:
a first conductive portion;
a second conductive portion; and
a sensor portion provided between the first conductive portion and the second conductive portion, the sensor portion including a first magnetic member and a first non-magnetic member, a second direction from the first magnetic member to the first non-magnetic member crossing a first direction from the first conductive portion to the second conductive portion, the first non-magnetic member including a first portion and a second portion, the second portion being between the first portion and the second conductive portion in the first direction;
a first terminal electrically connected to the first conductive portion;
a second terminal electrically connected to the second conductive portion;
a third terminal electrically connected to the first portion;
and a fourth terminal electrically connected to the second portion; and
a controller,
the controller being configured to supply a first current between the first terminal and the second terminal and to detect a first signal generated between the third terminal and the fourth terminal.

16. The magnetic sensor according to claim 15, wherein
the first signal changes in response to a component of a target magnetic field in a third direction, and
the third direction crosses a plane including the first direction and the second direction.

17. A magnetic recording device, comprising:
a magnetic head including the magnetic sensor according to claim 3;
a magnetic recording medium,
the target magnetic field corresponds to information recorded on the magnetic recording medium.

18. The magnetic recording device according to claim 17, wherein
a direction from the magnetic recording medium to the magnetic sensor is along the third direction.

19. The magnetic recording device according to claim 18, wherein
the first direction is along a down-track direction of the magnetic recording medium.

20. The magnetic recording device according to claim 18, wherein
the second direction is along a down-track direction of the magnetic recording medium.
